(19) United States
(12) Patent Application Publication
(10) Pub. No.: US 2001/0036689 A1
(43) Pub. Date: Nov. 1, 2001

(54) Low dielectric constant insulating film resin composition, method of forming low dielectric constant insulating film, and method of producing semiconductor device

(76) Inventor: Masakazu Muroyama, Kanagawa (JP)

Correspondence Address: SONNENSCHEIN NATH & ROSENTHAL, Wacker Drive Station, Sears Tower, P.O. Box #061080, Chicago, IL, 60606-1080, US

(21) Appl. No.: 09/875,818

(22) Filed: Jun. 6, 2001

Related U.S. Application Data
(62) Division of application No. 09/413,323, filed on Oct. 6, 1999.

(30) Foreign Application Priority Data
Oct. 6, 1998 (JP) P10-284375

(51) Int. Cl. H01L 21/00

(52) U.S. Cl. 438/149

(57) ABSTRACT

A low dielectric constant insulating film resin composition for a semiconductor device, comprising a polyaryl ether-based low dielectric constant insulating film material and an antioxidant, a method of forming a low dielectric constant insulating film for a semiconductor device including the steps of coating and drying the above resin composition on the surface of a substrate, and a method of producing a semiconductor device provided with the above low dielectric constant insulating film, effectively suppressing the generation of carbon dioxide or carbon monoxide due to an oxidation reaction when forming an low dielectric constant insulating film for a semiconductor device using a polyaryl ether-based low dielectric constant material.

### BACKGROUND OF THE INVENTION

1. Field of the Invention

The present invention relates to a low dielectric constant insulating film resin composition for a semiconductor device containing a polyaryl ether-based low dielectric constant insulating film material and an antioxidant, a method of forming an low dielectric constant insulating film for a semiconductor device characterized by the steps of coating and drying the above resin composition, and a method of producing a semiconductor device having the above low dielectric constant insulating film.

2. Description of the Related Art

In recent years, along with the need for miniaturization, reduction of power consumption, and increase of speed, etc. of semiconductor devices, studies have been conducted on reducing the dielectric constant of the interlayer insulating film in order to decrease the capacitance between interconnections as a means for realizing them.

For example, a method has been proposed of forming as such a low dielectric constant film an SiOF film by adding C₂F₆ or NF₃ as a source of fluorine to tetraethoxyorthosilicate (TEOS) (for example, 25th SSDM, 1993, p. 161; Extended Abstracts (The 40th Spring Meeting, 1993); The Japan Society of Applied Physics and Related Sciences, 1a-ZV-9; etc.) However, this SiOF film suffers from the problem that its hygroscopicity increases along with an increase of the fluorine introduced and, along with this, the film ends up remarkably deteriorating in quality.

To deal with this problem, an SiOF film formed by using an SiF₄/O₂ based gas has been proposed (for example, see Extended Abstracts (The 40th Spring Meeting, 1993); The Japan Society of Applied Physics and Related Sciences, 31p-ZV-1; etc.) However, the dielectric constant of the SiOF film resulting from this method is limited to about 3.8. No further reduction in the dielectric constant can be expected.

Therefore, an insulating film material consisting of an organic resin has been proposed aiming at reduction of the dielectric constant to less than 3.8. This insulating film using an organic resin is formed by, for example, thermal decomposition and thermal polymerization of a dimer material gas. The organic interlayer insulating film obtained by this method has a low dielectric constant of about 2.3 (for example, see VLSI/ULSI Multilevel Interconnection Conference, p. 207, 1996 etc.)

Recently, further, another method has been proposed of dissolving a pre-formed organic resin in a solvent and coating, drying, and firing this on a substrate by spin-coating so as to form an organic based interlayer insulating film. This method is attracting attention since it is simple and can utilize conventional forming equipment as it is to form a relatively low dielectric constant insulating film. As the organic-based low dielectric constant insulating film material, a polyimide resin etc. having both a high heat resistance and low dielectric constant have been proposed.

A polyimide resin or other organic resin composition, however, is extremely highly reactive with oxygen and gradually decomposes by oxidation in the air or is remarkably oxidized by the active oxygen generated in the process of manufacturing a semiconductor. It has been confirmed that an oxidation reaction causes the generation and accumulation of carbon dioxide or carbon monoxide in the organic-based low dielectric constant insulating film and its disassociation from inside the film at the later heating process.

Further, when using such a polyimide resin or other organic resin composition to for example form an interlayer insulating film of a semiconductor device, it becomes a cause of so-called “poisoned via failure” or a cause of deterioration of the bondability between the interlayer insulating film and interconnection layer in the step of, for example, filling a conductive substance into the contact holes etc.

To solve this problem, means such as forming the interlayer insulating film in nitrogen gas or another inert gas have been devised, but even using these methods, the slight amount of oxygen contained and heat cause the oxidation reaction to proceed, so the above problem has not been solved completely yet.

As a related art of the present invention, Japanese Unexamined Patent Publication (Kokai) No. 62-265350 discloses a polyimide resin composition comprised of 100 parts by weight of a polyimide resin having a repeating unit as shown in formula (A),

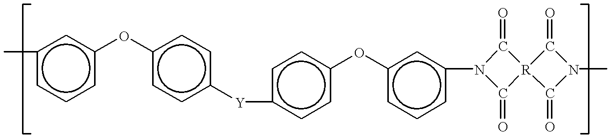

where, Y represents a straight C1 to C10 divalent hydrocarbon group etc. and

R represents a C2 or more aliphatic group, cyclic aliphatic group, etc.

and 5 to 100 parts by weight of an aromatic polyimide fiber and having an excellent moldability and mechanical strength. The publication also discloses that it is possible to add an antioxidant etc.

Further, Japanese Unexamined Patent Publication (Kokai) No. 2-115229 discloses a method of manufacturing a polyamideimide resin having excellent heat resistance, melt fluidity, and economicalness and having a small distribution of molecular weight characterized by causing a reaction among trimellitic acid anhydride or aromatic diisocyanate and, if necessary, a dicarboxylic acid and/or lactam in a polar solvent in the presence of an antioxidant.

Moreover, Japanese Unexamined Patent Publication (Kokai) No. 2-117957 discloses a polyamideimide resin composition with excellent mechanical strength, melt fluidity, and economicalness obtained by causing a reaction among trimellitic acid anhydride or aromatic diisocyanate and, if necessary, a dicarboxylic acid and/or lactam in a polar solvent and adding an antioxidant to the polyamideimide resin obtained.

The above publications, however, do not disclose that a resin composition comprising a polyamide resin or polyamideimide resin or other organic resin and an antioxidant is useful as a low dielectric constant insulating film material for a semiconductor device.

### SUMMARY OF THE INVENTION

The present invention has as its object to provide a simple technique for effectively suppressing the generation of carbon dioxide or carbon monoxide due to an oxidation reaction when using a polyaryl ether-based organic resin composition to form a low dielectric constant insulating film for a semiconductor device.

To achieve the above object, according to a first aspect of the present invention, there is provided a low dielectric constant insulating film resin composition of a semiconductor device comprising a polyaryl ether-based low dielectric constant insulating film material and an antioxidant.

In the low dielectric constant insulating film resin composition of the present invention, the polyaryl ether-based low dielectric constant insulating film material preferably comprises one or more polymers selected from the group comprising

a polymer containing the following structure:

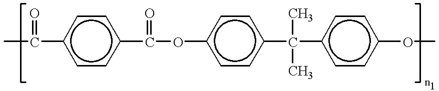

where, n₂ represents any natural number,

a polymer containing the following structure:

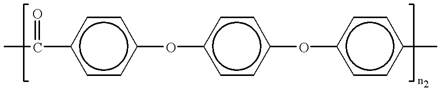

where, n₂ represents any natural number,

a polymer containing the following structure:

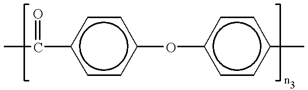

where, n₃ represents any natural number,

a polymer containing the following structure:

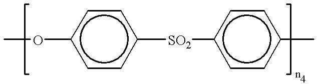

where, n₄ represents any natural number,

a polymer containing the following structure:

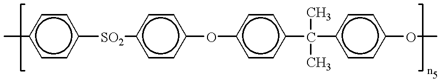

where, n₅ represents any natural number,

a polymer containing the following structure:

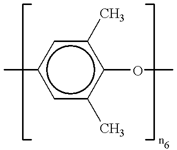

where, n₆ represents any natural number,

a polymer containing the following structure:

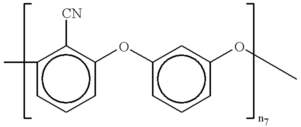

where, n₇ represents any natural number,

a polymer containing the following structure:

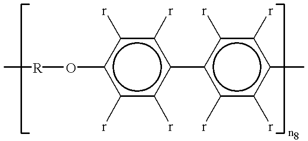

where, R represents a divalent substituent group,

r is the same or different and represents hydrogen or fluorine, and

n₈ represents any natural number.

In the low dielectric constant insulating film resin composition of the present invention, the antioxidant is preferably one or more antioxidant selected from the group comprising a phenol-based antioxidant, a sulfur-containing antioxidant, an amine-based antioxidant, and a phosphorus-containing antioxidant.

Further, the low dielectric constant insulating film for a semiconductor device of the present invention is preferably an interlayer insulating film of an semiconductor device and preferably has a dielectric constant of 3.0 or less.

Further, according to a second aspect of the present invention, there is provided a method of forming a low dielectric constant insulating film for a semiconductor device comprising the step of coating, drying, and firing on the surface of a substrate an insulating film resin composition for a semiconductor device comprising an organic low dielectric constant film material and an antioxidant.

In the method of forming a low dielectric constant insulating film for a semiconductor device of the present invention, the organic resin and the antioxidant can be selected from those listed above in for the low dielectric constant insulating film resin composition.

The low dielectric constant insulating film formed by the method of forming a low dielectric constant insulating film of the present invention preferably has a dielectric constant of 3.0 or less.

Further, the method of forming a low dielectric constant insulating film for a semiconductor device of the present invention preferably further comprises, after coating the low dielectric constant insulating film resin composition on the surface of the substrate, the step of drying at 50 to 200° C. and further heating to 300 to 500° C.

Moreover, according to a third aspect of the present invention, there is provided a method of producing a semiconductor device comprising the step of coating, drying, and firing on a semiconductor substrate having a semiconductor element an insulating film resin composition for a semiconductor device comprising a polyaryl ether-based low dielectric constant insulating film material and an antioxidant so as to form a low dielectric constant insulating film.

The method of producing a semiconductor device preferably further comprises the step of forming an antioxidation film on the low dielectric constant insulating film.

In the method of producing a semiconductor device of the present invention, the polyaryl ether-based low dielectric constant insulating film material and the antioxidant can be preferably selected from those listed above for the low dielectric constant insulating film resin composition.

Further, in the method of producing a semiconductor device of the present invention, the low dielectric constant insulating film is preferably an interlayer insulating film and preferably has a dielectric constant of 3.0 or less.

According to the present invention, when forming a low dielectric constant insulating film for a semiconductor device using a polyaryl ether-based low dielectric constant insulating film material, it is possible to effectively suppress the generation of carbon dioxide or carbon monoxide due to the oxidation reaction.

Further, the low dielectric constant insulating film of the present invention has a uniform film quality since the generation of carbon dioxide or carbon monoxide due to the oxidation reaction is effectively suppressed.

Therefore, for example, when forming an interlayer insulating film of a semiconductor device, this does not cause a poisoned via failure in the step of filling the contact holes with a conductive substance etc. and does not cause deterioration of the bondability between the interlayer insulating film and interconnection layer.

### BRIEF DESCRIPTION OF THE DRAWINGS

These and other objects and features of the present invention will become clearer from the following description of the preferred embodiments given with reference to the accompanying drawings, in which:

FIGS. 1A-1D are cross-sectional views of main steps in the method of producing a semiconductor device of the present invention and

FIGS. 2A-2D are cross-sectional views of main steps in the method of producing a semiconductor device of the present invention.

### DESCRIPTION OF THE PREFERRED EMBODIMENTS

Below, preferred embodiments will be described.

The low dielectric constant insulating film resin composition of the present invention is characterized by comprising a polyaryl ether-based low dielectric constant insulating film material and an antioxidant.

The polyether-based low dielectric constant insulating film material of one ingredient of the low dielectric constant insulating film resin composition of the present invention is a polymer containing a phenylether structure of the following chemical formula in the molecule:

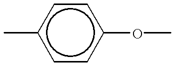

The polyaryl ether resin has high heat resistance due to its molecular structure and has an oxygen atom in its structure, so is a polymer promising an excellent bondability.

The above polyether-based low dielectric constant insulating film material may be selected, for example, from the following:

(1) a polymer containing the following structure (generic name: polyarylate):

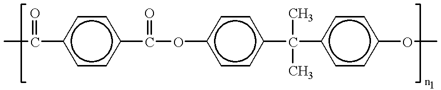

where, n₁ represents any natural number.

(2) a polymer containing the following structure (generic name: polyether ether ketone):

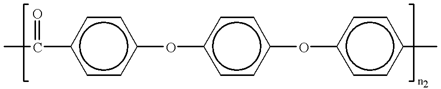

where, n₂ represents any natural number.

(3) a polymer containing the following structure (generic name: polyether ketone):

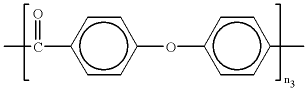

where, n₃ represents any natural number.

(4) a polymer containing the following structure (generic name: polyether sulfone):

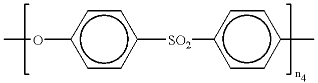

where, n₄ represents any natural number.

(5) a polymer containing the following structure (generic name: polysulfone):

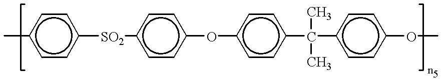

where, n₅ represents any natural number.

(6) a polymer containing the following structure (generic name: polyphenylene ether):

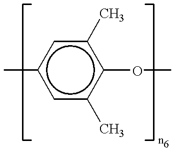

where, n, represents any natural number.

(7) a polymer containing the following structure (generic name: polyether nitrile):

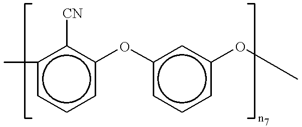

where, n₇ represents any natural number.

(8) a polymer containing the following structure (generic name: polybiphenyl ether):

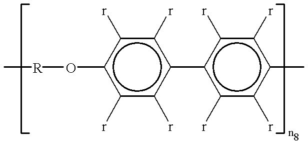

where, R represents a divalent substituent group,

r is the same or different and represents hydrogen or fluorine, and

n₈ represents any natural number.

The polyaryl ether-based low dielectric constant insulating film material has a high heat resistance and low dielectric constant, preferably has a dielectric constant of a dielectric constant of below 3.0. The above polymers (resins) need only be ones having both a high heat resistance and low dielectric constant. The method of manufacture, molecular weight, distribution of molecular weight, etc. are not particularly limited.

The antioxidant, another ingredient of the low dielectric constant resin composition of the present invention, is added to effectively prevent the organic resin from oxidation and deterioration.

The amount of the antioxidant added is an amount sufficient for prevention of oxidation of the organic resin, but is usually 0.1 to 3 wt % with respect to the resin composition. If the amount added is less than 0.1 wt %, the oxidation preventing effect is not sufficient, while if over 3 wt %, the antioxidant may precipitate on the surface resulting in a fall of the yield when forming the interconnections, causing a reduction in the dynamic characteristics of the resin composition, etc.

As the antioxidant able to be used for the present invention, for example, the following can be mentioned:

a phenol-based antioxidant such as hydroquinone, hydroquinone monomethylether, 2,5-di-t-butylhydro-quinone, 2,5-di-t-amylhydroquinone, t-butyl catechol, styrenated phenol, 2-t-butyl-4-methylphenol, 2,6-di-t-butyl phenol, polybutylated bisphenol A, 4,4′-dihydroxydiphenyl sulfone (bisphenol S), bisphenol A, thiobisphenol, 2,4,5-trihydroxybutylphenone, 2,6-di-t-butyl-4-methyl phenol, 4,6-di-t-butyl-2-methyl phenol, butyl hydroxyanisole, 2,2′-methylenebis(4-methyl-6-t-butylphenol), 4,4′-methylenebis(2,6-di-t-butylphenol), tris(2-methyl-4-hydroxy-5-t-butylphenol)butane, 1,3,5-triethyl-2,4,6-tris(3,5-di-t-butyl-4-hydroxybenzyl)benzen e, tetrakis[methylene-(3′,5′-di-t-butyl-4-hydroxycinnamat e)]methane, 1,3,5-tris(4-t-butyl-3-hydroxy-2,6-dimethylbenzyl)isocyanurate, 1,3,5-tris(3,5-di-t-butyl-4-hydroxybenzyl) isocyanurate, IRGANOX245, IRGANOX259, IRGANOX565, IRGANOX1010, IRGANOX1035, IRGANOX1076, IRGANOX1081, IRGANOX1098, IRGANOX1222, IRGANOX1330, IRGANOX1425WL (brandname of Ciba-Geigy), etc.,

a sulfur-containing antioxidant such as dilauryl thiopropionate, dimyristyl thiopropionate, distearyl thiodipropionate, laurylstearyl thiodipropionate, pentaerythritol tetrakis(3-lauryl thiopropionate), 4,4′-thiobis(3-methyl-6-t-butylphenol), 2,2′-thiobis(4-methyl-6-t-butylphenol), bis(3-methyl-4-hydroxy-5-t-butylbenzyl)sulfide, 2-mercaptobenzoimidazole, etc.,

an amine-based antioxidant such as hydroxylamine, N-n-butyl-p-aminophenol, octylated diphenylamine, N,N′-diisopropyl-p-phenylenediamine, N,N′-di-sec-butyl-p-phenylenediamine, N,N′-bis(1,4-dimethylpentyl)-p-phenylen ediamine, N,N′-bis(1-ethyl-3-methylpentyl)-p-phenylenediamine, N-phenyl-N′-isopropyl-p-phenylenediamine, N,N′-diphenyl-p-phenylenediamine, N,N′-di-β-naphthyl-p-phenylenediamine, phenothiazine, N-phenyl-α-naphthylamine, etc.,

a phosphorus-containing antioxidant such as triphenyl phosphite, trioctadecyl phosphite, tridecyl phosphite, trilauryl triphosphite, etc.

The low dielectric constant insulating film resin composition for a semiconductor device of the present invention can be prepared by, for example, mixing the polyaryl ether-based low dielectric constant insulating film material and the antioxidant in an appropriate ratio, and then, if necessary, diluting with an appropriate inert solvent.

As the diluent, one or more inert solvents may be mentioned from, for example, alcohols such as methanol and ethanol, esters such as ethyl acetate, ketones such as acetone, methyl ethyl ketone, methyl isobutyl ketone, and cyclohexanone, hydrocarbons such as hexane, heptane, and cyclohexane, aromatic hydrocarbons such as benzene, toluene, and xylene, fluorinates, glycol acetates such as ethylene glycol monomethylacetate, and ethylene glycol diacetate, and amides such as N,N-methyl-2-pyrrolidone.

The obtained low dielectric constant insulating film resin composition of the present invention is then coated on a substrate (or a semiconductor substrate), then is pre-dried at around 50 to 200° C., then dried at 200 to 300° C. to form the low dielectric constant insulating film for a semiconductor device of the present invention.

As the method of coating on the substrate (or the semiconductor substrate), for example, dip coating, spin coating, spray pyrolysis, etc. can be used. In the above methods, spin coating which uses a spin coater to spin-coat and dry the resin composition on the substrate is preferred. The amount of coating on the substrate is freely selected depending on the location of use of the insulating film.

The pre-drying temperature is from the boiling point of the solvent used to 250° C., preferably 50 to 200° C. If the drying temperature is below 50° C., the solvent may remain.

Generally, the drying temperature is about 200 to 300° C. This is for completely removing the solvent remaining in the insulating film. If above 300° C., deterioration of the film quality may be caused.

Note that the insulating film is preferably formed in a nitrogen or other inert gas atmosphere or in an oxygen-free hypervacuum.

Further, as the method as forming the low dielectric constant insulating film for a semiconductor device of the present invention, there is also the method of mixing a precursor of the organic resin (monomer or oligomer) and the antioxidant in an appropriate ratio, coating an organic resin precursor composition obtained by diluting this with an inert solvent by spin-coating etc., drying at 50 to 200° C., then firing at 200 to 500° C.

Note that in the semiconductor device of the present invention, it is also preferable to further form an antioxidation film on the low dielectric constant insulating film consisting of the organic resin. By forming such an antioxidation film, it is possible to reduce the amount of the antioxidant mixed in the organic resin and thereby prevent oxidation more effectively. As a material for forming the antioxidation film, for example, the materials listed above for the antioxidants may be mentioned.

The low dielectric constant insulating film formed in the above way has a dielectric constant (ε) of 3.0 or less, preferably 2.5 or less. In the related art, there was the problem that the dielectric constant was low, but the oxidation reaction caused a deterioration of the film quality, but according to the present invention, it is possible to obtain a low dielectric constant insulating film comprising an organic resin having an excellent film quality while maintaining the low dielectric constant and heat resistance.

The above method of forming a low dielectric constant insulating film can be preferably applied to the production of a semiconductor device having the dielectric constant insulating film as an interlayer insulating film. Note that it is also possible to form metal interconnections in several layers separated by such interlayer insulating films.

The semiconductor device having the low dielectric constant insulating film as an interlayer insulating film has a reduced capacitance between interconnections. Therefore, it is possible to obtain a semiconductor device carrying a high-speed device on it with a high reliability.

Below, the present invention will be explained in more detail with references to examples. The invention is not of course limited to these examples in any way.

### EXAMPLE 1

First, 100 parts by weight of a polymer having a repeating unit of

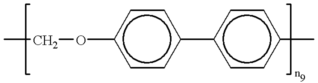

where, n₉ represents any natural number was mixed as a polyaryl ether-based low dielectric constant insulating film material with 1 part by weight of hydroxylamine (NH₂OH) as an antioxidant to obtain a low dielectric constant insulating film resin composition.

Next, the low dielectric constant insulating film resin composition obtained above was heated to 400° C. in an atmosphere of 20% oxygen concentration and then measured for weight loss by thermogravimetric analysis (TG) using a thermogravimeter, whereupon a weight loss of 0.5% was observed.

### COMPARATIVE EXAMPLE 1

Except for not adding hydroxylamine, the same procedure was performed as in Example 1 to prepare the low dielectric constant resin composition of the comparative example. This was treated in the same way as in Example 1, that is, heated to 400° C. in an atmosphere of 20% oxygen concentration and measured for weight loss by TG, whereupon a weight loss of 5% was observed.

From the above, it was learned that the amounts of carbon dioxide and carbon monoxide generated by the oxidation reaction and remaining in the resin were greatly reduced in Example 1 compared with Comparative Example 1 and that due to the addition of the antioxidant, the resin composition of Example 1 is excellent in antioxidation effect.

### EXAMPLE 2

First, 100 parts by weight of the same polyaryl ether-based low dielectric constant insulating film material as used in Example 1 and 1 part by weight of methylamine as an antioxidant were mixed to prepare a low dielectric constant insulating film resin composition.

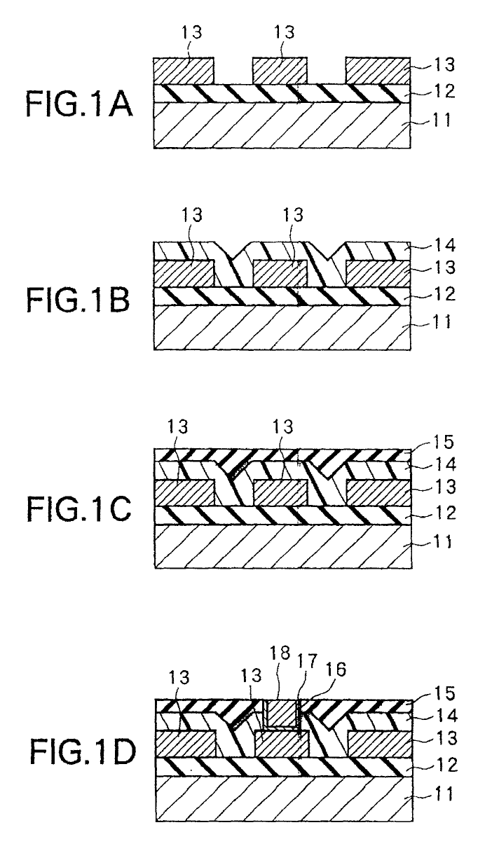

On the other hand, as shown in FIG. 1A, a wafer was prepared comprised of a silicon semiconductor substrate 11 formed with not shown semiconductor elements and an interlayer insulating film (silicon oxide film) 12 and aluminum interconnection layer 13 formed on it by an ordinary method. Next, as shown in FIG. 1B, the low dielectric constant insulating film resin composition containing polyaryl ether and methylamine was spin-coated and dried to form a low dielectric constant insulating film 14 to a thickness of 700 nm.

The conditions of forming the low dielectric constant insulating film were as follows:

Conditions for Forming Low Dielectric Constant Insulating Film

Speed of spin-coater: 2500 rpm/3 min

Coating temperature: 25° C.

Atmosphere: nitrogen atmosphere

Drying conditions: 100° C. for 30 min, then 250° C. for 30 min

Next, as shown in FIG. 1C, the low dielectric constant insulating film 14 was treated by CVD using TEOS to form a silicon oxide film 15 to a thickness of 700 nm. The CMP method was then used to planarize the top surface of the silicon oxide layer 15.

Next, as shown in FIG. 1D, a lithography step and reactive ion etching were used to form contact holes 16, then a titanium nitride layer 17 was formed as a bonding layer on the bottom and side walls of the contact holes 16 by sputtering.

Next, tungsten was deposited over the entire surface by CVD so as to fill the contact holes 16, then dry-etching was used to form contact plugs 18 consisting of tungsten.

The performance of the tungsten filling in the contact plugs 18 obtained in the above way was evaluated resulting in a yield of 100%.

After this, while not shown in the figures, an upper aluminum interconnection layer was formed in contact with the lower aluminum interconnection layer 13 via the contact plugs 18, then a passivation film consisting of silicon oxide was formed on it to thereby produce the desired semiconductor device.

### COMPARATIVE EXAMPLE 2

Except for using a low dielectric constant resin composition without methylamine, the same procedure was followed as in Example 2 to produce a semiconductor device having the same layer configuration as that shown in FIG. 1D. The performance of the tungsten filling was tested resulting in a yield of 15%. Compared with Example 2 using a resin composition to which methylamine was added as an antioxidant, a clear decline in the yield was seen.

From the above, it was learned that the performance of the tungsten filling of the contact plugs of the semiconductor device of Example 2 formed using a low dielectric constant insulating film resin composition containing an antioxidant was far superior to that of Comparative Example using a low dielectric constant insulating film resin composition without an antioxidant.

### EXAMPLE 3

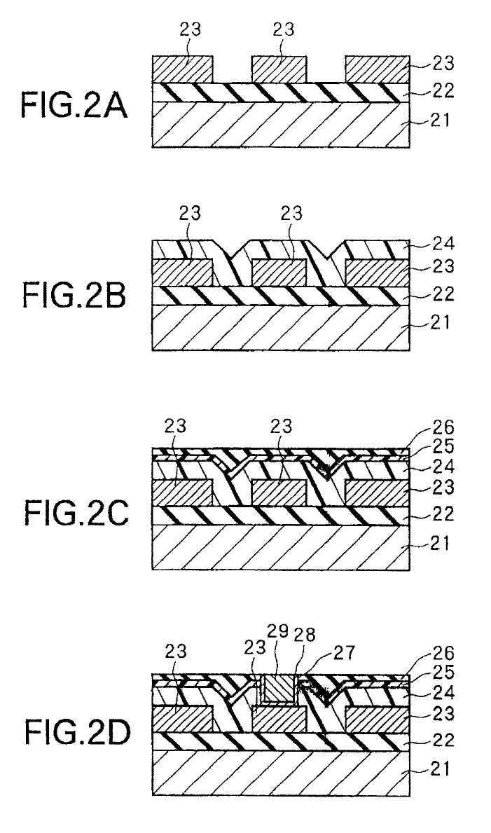

First, as shown in FIG. 2A, a wafer was prepared comprised of a silicon semiconductor substrate 21 formed with not shown semiconductor elements and an interlayer insulating film (silicon oxide film) 22 and aluminum interconnection layer 23 formed on it.

Next, as shown in FIG. 2B, a low dielectric constant insulating film resin composition obtained by mixing 100 parts by weight of the same polyaryl ether-based low dielectric constant insulating film material as that used in Example 1 and 1 part by weight of aniline as an antioxidant and diluted in hexane or another inert solvent was coated and dried on the wafer by spin-coating under the following conditions to form a low dielectric constant insulating film 24 on the wafer:

Conditions for Forming Low Dielectric Constant Insulating Film

Speed of spin-coater: 2500 rpm/3 min

Coating temperature: 25° C.

Atmosphere: nitrogen atmosphere

Drying conditions: 100° C. for 30 min, then 250° C. for 60 min

Next, a hydroxylamine layer (antioxidation film) 25 was formed on the low dielectric constant insulating film 24.

After that, a silicon oxide film 26 was formed by CVD using TEOS, then the conventional CMP was used to planarize the top surface of the silicon oxide film 26 to obtain the structure shown in FIG. 2C.

Next, a lithography step and reactive ion etching were used to form contact holes, then a titanium nitride layer 28 was formed as a bonding layer on the bottom and side walls of the contact holes by sputtering.

Next, tungsten was deposited over the entire surface of the titanium nitride layer 28 by CVD so as to fill the contact holes, then dry-etching was used to form contact plugs 29 consisting of tungsten.

The performance of the tungsten filling in the contact plugs 29 obtained in the above way was evaluated resulting in a yield of 100%.

After this, while not shown in the figures, an upper aluminum interconnection layer was formed in contact with the lower aluminum interconnection layer 23 via the contact plugs 29, then a passivation film consisting of silicon oxide was formed on it to thereby produce the desired semiconductor device.

According to Example 3, by forming the hydroxylamine layer 25 as an antioxidation film (processing layer) on the low dielectric constant insulating film (organic resin film) 24, it is possible to reduce the concentration of the antioxidant in the organic resin film 24 and to prevent oxidation more effectively.

### COMPARATIVE EXAMPLE 3

Except for using a low dielectric constant resin composition without aniline was used, the same procedure was followed as in Example 3 to produce a semiconductor device having the layer configuration as that shown in FIG. 2D. The performance of the tungsten filling was evaluated resulting in a yield of 15%. Compared with Example 3 using a resin composition with aniline added as an antioxidant, a clear decline in the yield was seen.

From the above, it was learned that the performance of the tungsten filling of the contact plugs of the semiconductor device of Example 3 formed using a low dielectric constant insulating film resin composition containing an antioxidant is far superior to that of Comparative Example 3 using a low dielectric constant insulating film resin composition without an antioxidant.

Summarizing the effects of the invention, according to the present invention, when forming a low dielectric constant insulating film for a semiconductor device using a polyaryl ether-based low dielectric constant insulating film resin composition, it is possible to effectively suppress the generation of carbon dioxide or carbon monoxide due to the oxidation reaction. Further, the low dielectric constant insulating film of the present invention has a uniform quality since the generation of carbon dioxide or carbon monoxide due to the oxidation reaction is suppressed effectively. Therefore, when forming this as an interlayer insulating film of a semiconductor device, it does not cause poisoned via failure in the step of filling the contact holes with a conductive substance etc. and does not cause deterioration of the bondability between the interlayer insulating film and interconnection layer.

Further, when further forming an antioxidation film on a low dielectric constant insulating film consisting of a polyaryl ether-based low dielectric constant insulating film resin, it is possible to reduce the amount of antioxidant added in the polyaryl ether-based low dielectric constant insulating film resin composition and to prevent oxidation more effectively.

Further, the semiconductor device of the present invention uses a low dielectric constant insulating film comprising a low dielectric constant film material and antioxidant and having a low dielectric constant and heat resistance for the interlayer insulating film between the interconnection layers. Therefore, it is a semiconductor device which is remarkably reduced in capacitance between interconnections, superior in heat resistance, and high in reliability. Therefore, since the capacitance between interconnections is reduced, this semiconductor device having a low dielectric constant insulating film as an interlayer insulating film can give a semiconductor device carrying high-speed devices with a high reliability.

What is claimed is:

1. A low dielectric constant insulating film resin composition for a semiconductor device, comprising:
a polyaryl ether-based low dielectric constant insulating film material and
an antioxidant.

2. A low dielectric constant insulating film resin composition for a semiconductor device as set forth in claim 1, wherein the polyaryl ether-based low dielectric constant insulating film material comprises at least one polymer selected from the group comprising:
a polymer containing the following structure: 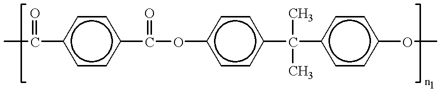
where, n₁ represents any natural number,
a polymer containing the following structure: 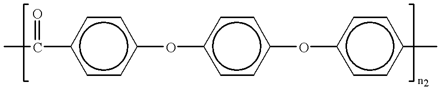
where, n₂ represents any natural number,
a polymer containing the following structure: 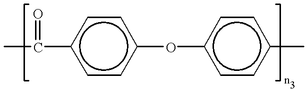
where, n₃ represents any natural number,
a polymer containing the following structure: 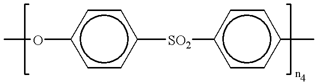
where, n₄ represents any natural number,
a polymer containing the following structure: 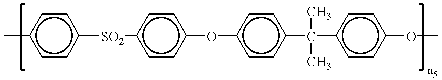
where, n₅ represents any natural number,
a polymer containing the following structure: 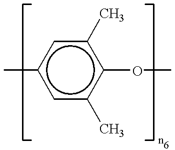
where, n₆ represents any natural number,
a polymer containing the following structure: 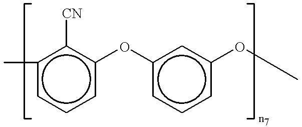
where, n₇ represents any natural number,
a polymer containing the following structure: 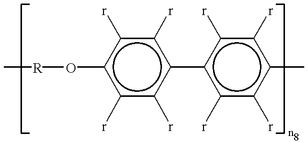
where, R represents a divalent substituent group,
r is the same or different and represents hydrogen or fluorine, and
n₈ represents any natural number.

3. A low dielectric constant insulating film resin composition for a semiconductor device as set forth in claim 1, wherein to antioxidant is at least one antioxidant selected from the group comprising a phenol-based antioxidant, a sulfur-containing antioxidant, an amine-based antioxidant, and a phosphorus-containing antioxidant.

4. A low dielectric constant insulating film for a semiconductor devices, comprising:
a polyaryl ether-based low dielectric constant insulating film material and
an antioxidant.

5. A low dielectric constant insulating film for a semiconductor device as set forth in claim 4, wherein the low dielectric constant insulating film comprises a film with a low dielectric constant of not more than 3.0.

6. A low dielectric constant insulating film for a semiconductor device as set forth claim 4, wherein the polyaryl ether-based low dielectric constant insulating film material comprises at least one polymer selected from the group comprising:
a polymer containing the following structure: 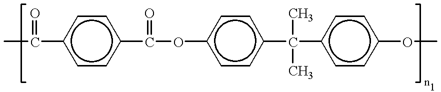
where, n₁ represents any natural number,
a polymer containing the following structure: 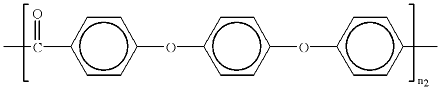
where, n₂ represent any natural number,
a polymer containing the following structure: 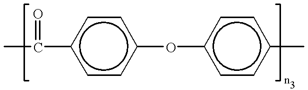
where, n₃ represents any natural number,
a polymer containing the following structure: 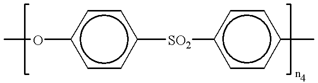
where, n₄ represents any natural number,
a polymer containing the following structure: 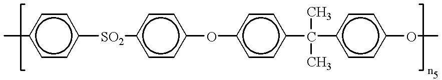
where, n₅ represents any natural number,
a polymer containing the following structure: 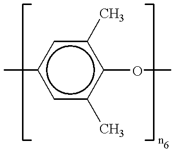
where, n₆ represents any natural number,
a polymer containing the following structure: 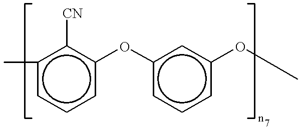
where, n₇ represents any natural number,
a polymer containing the following structure: 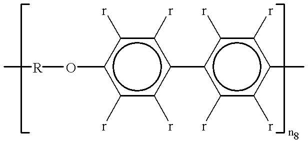
where, R represents a divalent substituent group, r is the same or different and represents hydrogen or fluorine, and n₈ represents any natural number.

7. A low dielectric constant insulating film for a semiconductor device as set for in claim 4, wherein the antioxidant comprises at least one antioxidant selected from the group comprising a phenol-based antioxidant, a sulfur-containing antioxidant, an amine-based antioxidant, and a phosphorus-containing antioxidant.

8. A method for forming a low dielectric constant insulating film for a semiconductor device comprising a step of coating and drying on the surface of a substrate an insulating film resin composition for a semiconductor device containing a polyaryl ether-based low dielectric constant insulating film material and an antioxidant.

9. A method for forming a low dielectric constant insulating film for a semiconductor device as set forth in claim 8, wherein the low dielectric constant insulating film comprises a film with a dielectric constant of not more than 3.0.

10. A method for forming a low dielectric constant insulating film for a semiconductor device as set forth in claim 8, wherein the polyaryl ether-based low dielectric constant insulating film material comprises at least one polymer selected from the group comprising:
a polymer containing the following structure: 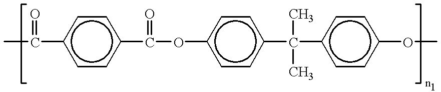
where, n₁ represents any natural number,
a polymer containing the following structure: 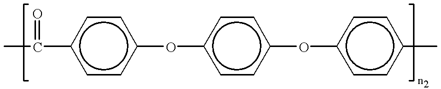
where, n₂ represents any natural number,
a polymer containing the following structure: 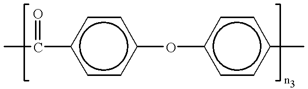
where, n₃ represents any natural number,
a polymer containing the following structure: 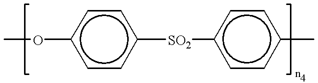
where, n₄ represents any natural number,
a polymer containing the following structure: 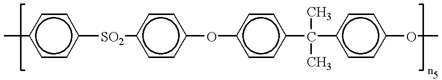
where, n₅ represents any natural number,
a polymer containing the following structure: 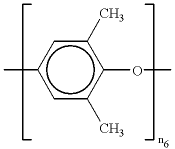
where, n₆ represents any natural number,
a polymer containing the following structure: 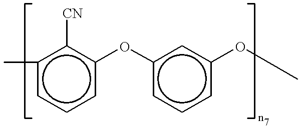
where, n₇ represents any natural number,
a polymer containing the following structure: 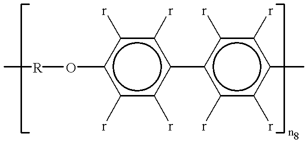
where, R represents a divalent substituent group, r is the same or different and represents hydrogen or fluorine, and n₈ represents any natural number.

11. A method for forming a low dielectric constant insulating film for a semiconductor device as set forth in claim 8, wherein the antioxidant comprises at least one antioxidant selected from the group comprising a phenol-based antioxidant, a sulfur-containing antioxidant, an amine-based antioxidant, and a phosphorus-containing antioxidant.

12. A method for producing a semiconductor device comprising a step of forming a low dielectric constant insulating film by coating and drying on the surface of a substrate formed with semiconductor elements an insulating film resin composition for a semiconductor device containing a polyaryl ether-based low dielectric constant insulating film material and an antioxidant.

13. A method for producing a semiconductor device as set forth in claim 12, wherein the low dielectric constant insulating film comprises a film with a dielectric constant of not more than 3.0.

14. A method for producing a semiconductor device as set forth in claim 12, wherein the polyaryl ether-based low dielectric constant insulating film material comprises at least one polymer selected from the group comprising:
a polymer containing the following structure: 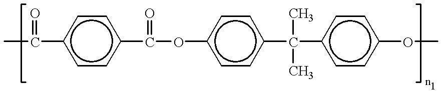
where, n₁ represents any natural number,
a polymer containing the following structure: 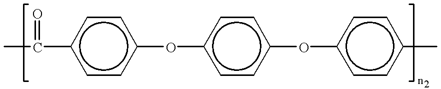
where, n₂ represents any natural number,
a polymer containing the following structure: 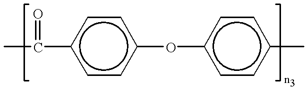
where, n₃ represents any natural number,
a polymer containing the following structure: 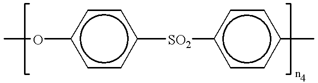
where, n₄ represents any natural number,
a polymer containing the following structure: 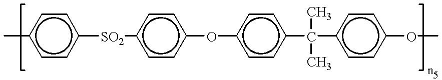
where, n₅ represents any natural number,
a polymer containing the following structure: 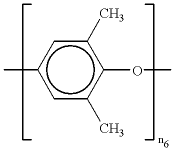
where, n₆ represents any natural number,
a polymer containing the following structure: 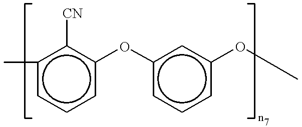
where, n₇ represents any natural number,
a polymer containing the following structure: 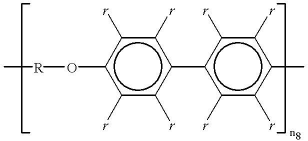
where, R represents a divalent substituent group, r is the same or different and represents hydrogen or fluorine, and n₈ represents any natural number.

15. A method for producing a semiconductor device as set forth in claim 12, wherein the antioxidant is at least one antioxidant selected from the group comprising a phenol-based antioxidant, a sulfur-containing antioxidant, an amine-based antioxidant, and a phosphorus-containing antioxidant.

16. A method for producing a semiconductor device as set forth in claim 12, further comprising the step of forming an antioxidation film on the low dielectric constant insulating film.
